(19) United States
(12) Patent Application Publication
(10) Pub. No.: US 2026/0212934 A1
(43) Pub. Date: Jul. 23, 2026

(54) SEAMLESS RANDOM READ

(71) Applicant: Micron Technology, Inc., Boise, ID (US)

(72) Inventors: Andrea Martinelli, BERGAMO (IT); Ferdinando Bedeschi, Biassono (IT); Walter Di Francesco, AVEZZANO (IT)

(73) Assignee: Micron Technology, Inc., Boise, ID (US)

(21) Appl. No.: 19/446,587

(22) Filed: Jan. 12, 2026

Related U.S. Application Data
(60) Provisional application No. 63/748,923, filed on Jan. 23, 2025.

(51) Int. Cl. G11C 16/26; G11C 16/30; G11C 16/32

(52) U.S. Cl. CPC G11C 16/26; G11C 16/30; G11C 16/32

(57) ABSTRACT

A method for performing random read operations on memory cells is provided. The method comprises receiving identification of a list of target blocks of the array of memory cells that need to be opened for random read operations. The method further comprises opening the list of target blocks before performing read operations on any one of the list of target blocks. The method further comprises performing read operations on the list of target blocks. The method further comprises closing the list of target blocks.

### RELATED APPLICATIONS

This application claims priority to U.S. Provisional Application No. 63/748,923, filed on Jan. 23, 2025, entitled “SEAMLESS RANDOM READ.” The contents of U.S. Provisional Application No. 63/748,923 are incorporated herein in their entirety for all purposes.

### TECHNICAL FIELD

This disclosure relates to one or more systems for memory, including techniques for performing random read operations on memory cells.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1A illustrates examples of a host system and a memory system that support techniques for performing random read operations on memory cells, in accordance with examples as disclosed herein.

FIG. 1B is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIG. 4 is a timing diagram illustrating a memory access operation on a target memory block in accordance with examples as disclosed herein.

FIG. 5 is a timing diagram illustrating memory read operations accessing memory cells across two memory blocks in a random read scenario, in accordance with examples as disclosed herein.

FIG. 6 is a timing diagram illustrating memory read operations accessing memory cells across two memory blocks in a random read scenario using “warm-up all-at-once” approach, in accordance with examples as disclosed herein.

FIG. 7 is a timing diagram illustrating memory read operations accessing memory cells across two memory blocks in a random read scenario using “warm-up on-need” approach, in accordance with examples as disclosed herein.

FIG. 8 is a flowchart illustrating a method for performing random read operations on two target blocks using the warm-up on-need approach, in accordance with examples as disclosed herein.

FIG. 9 is a flowchart illustrating a method for performing random read operations on a list of target blocks using the warm-up all-at-once approach, in accordance with examples as disclosed herein.

### DETAILED DESCRIPTION

In a NAND device, a memory read operation for accessing a selected memory cell in a memory block generally involves three phases, namely, the opening phase, the sensing phase, and the closing phase. During the opening phase, bias voltages of the word lines in the memory block are ramped up by voltage generation devices, such as word line pumps. In the sensing phase, the threshold level of the selected memory cell is detected. Finally, in the closing phase, the word lines in the memory block are discharged.

Traditional methods for performing a series of read operations across multiple memory cells in different memory blocks involve repeating the full read operation cycle (including all three phases) for each memory cell. These methods fail to account for whether a memory block has been recently accessed or will be accessed in the near future, resulting in redundant opening and closing of memory blocks. This inefficiency increases overall access time and reduces performance, particularly when multiple memory cells are accessed in random read sequences.

The present disclosure addresses these limitations by introducing methods to optimize memory access operations. In one embodiment, to perform read access on a series of memory blocks, a memory controller opens the series of memory blocks in parallel, performs multiple sensing operations, and closes the memory blocks in parallel after the sensing operations are complete. In another embodiment, the memory controller employs timers to monitor the status of opened blocks and closes a block when its timer expires. These disclosed methods can reduce redundant operations, minimize access latency, and enhance overall performance and efficiency.

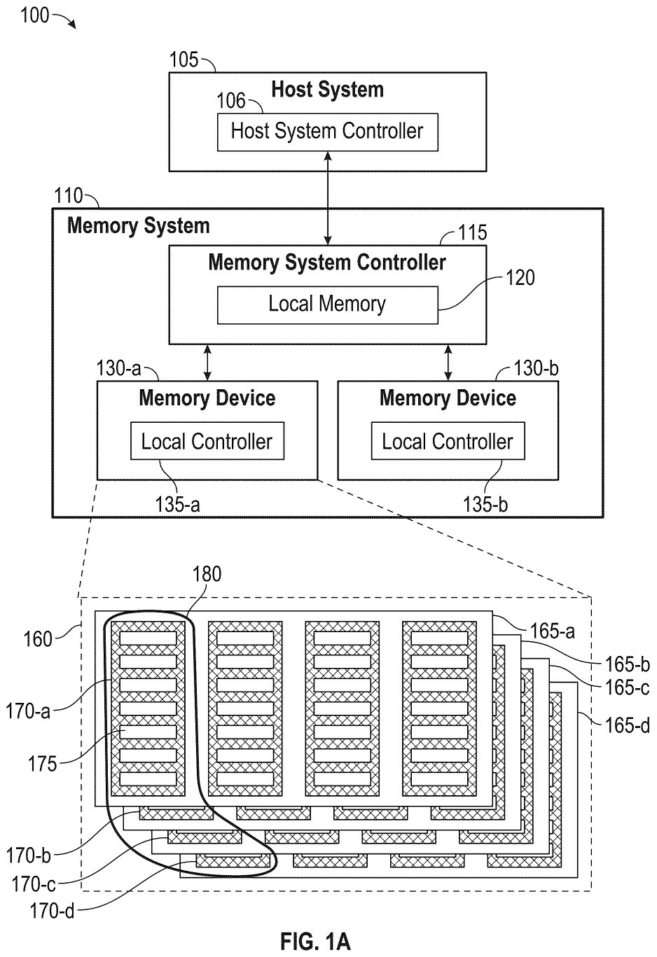

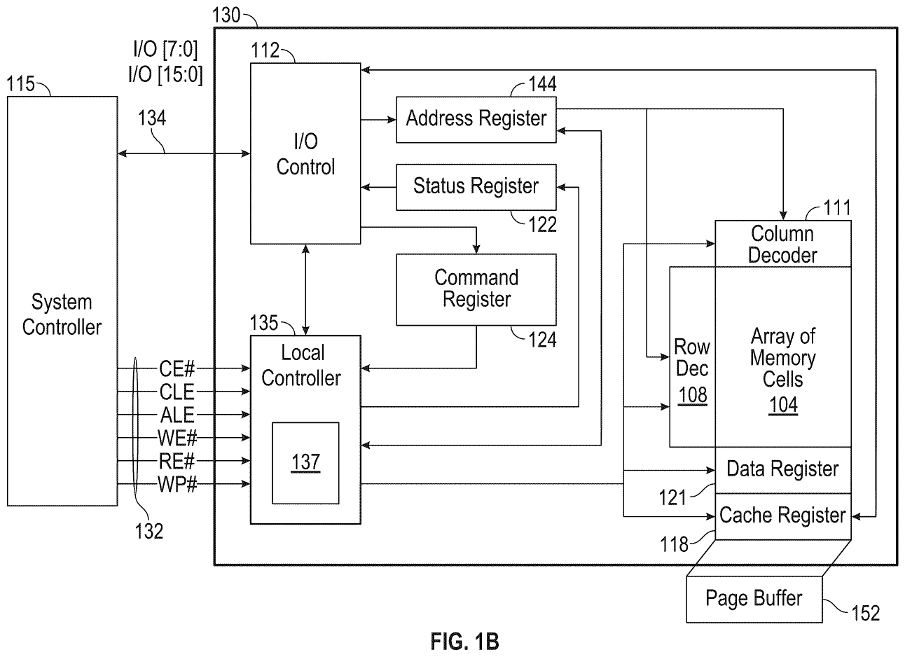

FIG. 1A illustrates an example of a system 100 that supports techniques for performing random read operations on memory cells, in accordance with examples as disclosed herein. System 100 includes a host system 105 coupled with a memory system 110. System 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

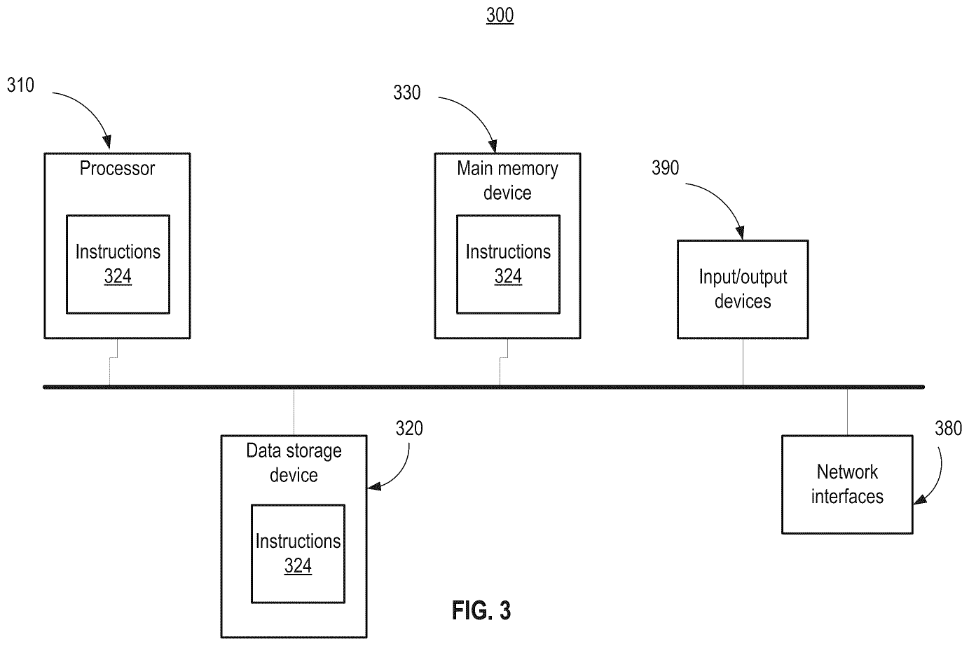

System 100 may include a host system 105, which may be coupled with memory system 110. In some examples, this coupling may include an interface with a host system controller 106, which may be an example of a controller or control component configured to cause host system 105 to perform various operations in accordance with examples as described herein. Host system 105 may include one or more devices and, in some cases, may include a processor chipset and a software stack executed by the processor chipset. Host system 105 may be implemented by, for example, an apparatus 300 shown in FIG. 3. For example, host system 105 may include an application configured for communicating with memory system 110 or a device therein. The processor chipset may include one or more cores, one or more caches (e.g., memory local to or included in host system 105), a memory controller (e.g., NVDIMM controller), and a storage protocol controller (e.g., peripheral component interconnect express (PCIe) controller, serial advanced technology attachment (SATA) controller). Host system 105 may use memory system 110, for example, to write data to memory system 110 and read data from memory system 110. Although one memory system 110 is shown in FIG. 1A, the host system 105 may be coupled with any quantity of memory systems 110.

Host system 105 may be coupled with memory system 110 via at least one physical host interface. Host system 105 and memory system 110 may, in some cases, be configured to communicate via a physical host interface using an associated protocol (e.g., to exchange or otherwise communicate control, address, data, and other signals between memory system 110 and host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a Graphical Double Data Rate (GDDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of host system 105 and a system controller 115 of memory system 110. In some examples, host system 105 may be coupled with memory system 110 (e.g., host system controller 106 may be coupled with system controller 115) via a respective physical host interface for each memory device 130 included in the memory system 110, or via a respective physical host interface for each type of memory device 130 included in memory system 110.

Memory system 110 may include a system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1A, memory system 110 may include any quantity of memory devices 130. Further, if the memory system 110 includes more than one memory device 130, different memory devices 130 within the memory system 110 may include the same or different types of memory cells.

System controller 115 may be coupled with and communicate with host system 105 (e.g., via the physical host interface) and may be an example of a controller or control component configured to cause memory system 110 to perform various operations in accordance with examples as described herein. System controller 115 may also be coupled with and communicate with memory devices 130 to perform operations such as reading data, writing data, erasing data, or refreshing data at a memory device 130—among other such operations—which may generically be referred to as access operations. In some cases, system controller 115 may receive commands from the host system 105 and communicate with one or more memory devices 130 to execute such commands (e.g., at memory arrays within the one or more memory devices 130). For example, system controller 115 may receive commands or operations from host system 105 and may convert the commands or operations into instructions or appropriate commands to achieve the desired access of memory devices 130. In some cases, system controller 115 may exchange data with host system 105 and with one or more memory devices 130 (e.g., in response to or otherwise in association with commands from host system 105). For example, system controller 115 may convert responses (e.g., data packets or other signals) associated with the memory devices 130 into corresponding signals for the host system 105.

System controller 115 may be configured for other operations associated with the memory devices 130. For example, the system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from host system 105 and physical addresses (e.g., physical block addresses) associated with memory cells within memory devices 130.

The system controller 115 may include hardware such as one or more integrated circuits or discrete components, a buffer memory, or a combination thereof. The hardware may include circuitry with dedicated (e.g., hard-coded) logic to perform the operations ascribed herein to system controller 115. System controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

System controller 115 may also include a local memory 120. In some cases, local memory 120 may include read-only memory (ROM) or other memory that may store operating code (e.g., executable instructions) executable by system controller 115 to perform functions ascribed herein to system controller 115. In some cases, local memory 120 may additionally, or alternatively, include static random access memory (SRAM) or other memory that may be used by system controller 115 for internal storage or calculations, for example, related to the functions ascribed herein to system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same semiconductor die or within a same package) a local controller 135, which may execute operations on one or more memory cells of the respective memory device 130. A local controller 135 may operate in conjunction with a system controller 115 or may perform one or more functions ascribed herein to the system controller 115. For example, as illustrated in FIG. 1A, a memory device 130-a may include a local controller 135-a and a memory device 130-b may include a local controller 135-b. In the examples illustrated in this disclosure (e.g., the example shown in FIG. 1B), local controller 135 is disposed on the same semiconductor die as the memory array (e.g., array 104); and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of memory blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of memory blocks 170 and, in some cases, concurrent operations may be performed on different planes 165. For example, concurrent operations may be performed on memory cells within different blocks 170 so long as the different blocks 170 are in different planes 165. In some cases, an individual memory block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165- b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line). Example memory cells structures are shown in more detail below using illustrative schematics.

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, L2P (logical-to-physical) mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system 110 may utilize a system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

System 100 may include any quantity of non-transitory computer readable media that support techniques for logical-to-physical table compression. For example, host system 105 (e.g., a host system controller 106), memory system 110 (e.g., a system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a system controller 115), or by a memory device 130 (e.g., by a local controller 135), may cause the host system 105, the memory system 110, or the memory device 130 to perform associated functions as described herein.

FIG. 1B is a simplified block diagram of a memory device 130 in communication with a system controller 115 of a memory system (e.g., the memory system 110 of FIG. 1A), according to an embodiment. As shown in FIG. 1B and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states for storing any number of bits of information.

With continued reference to FIG. 1B, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1B, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

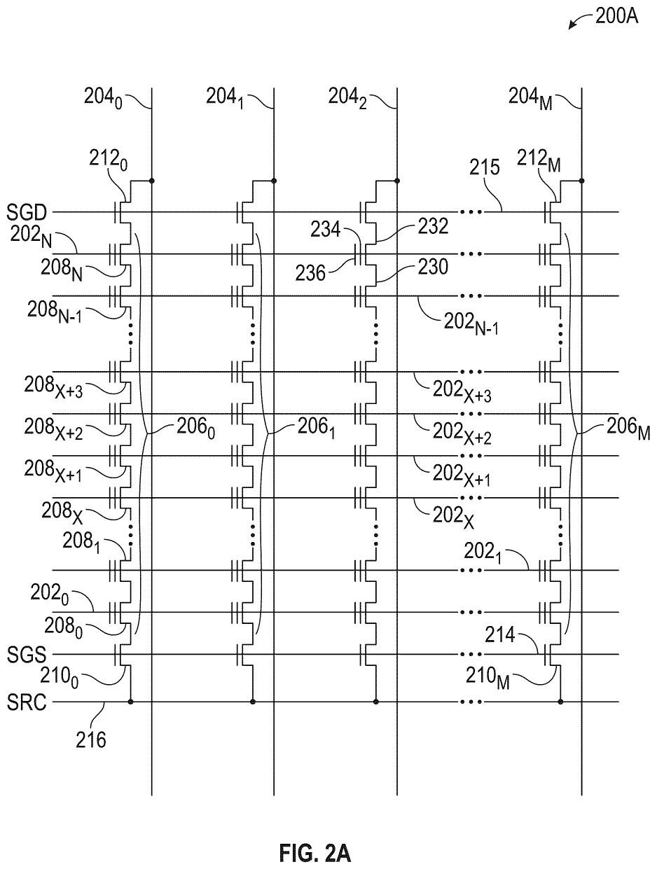

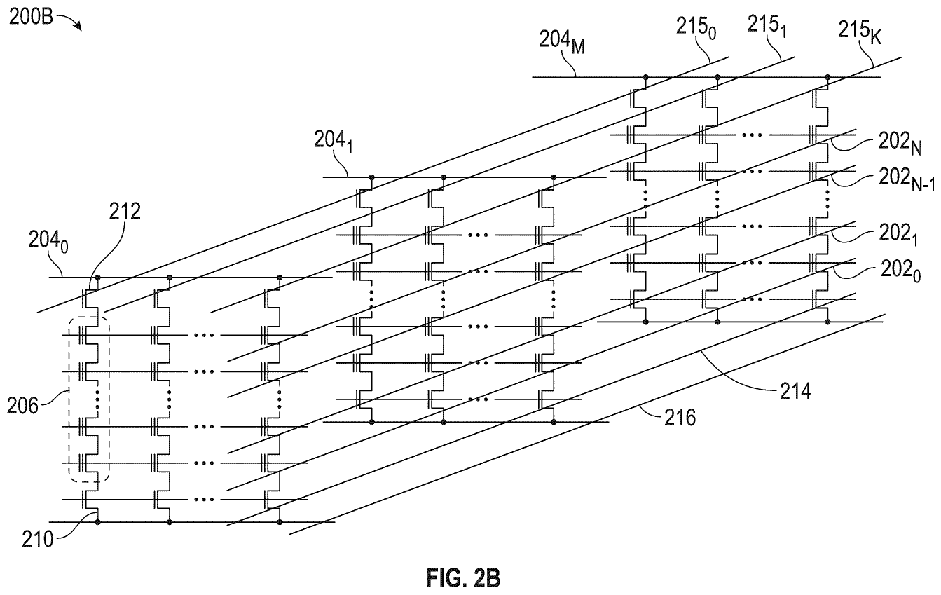

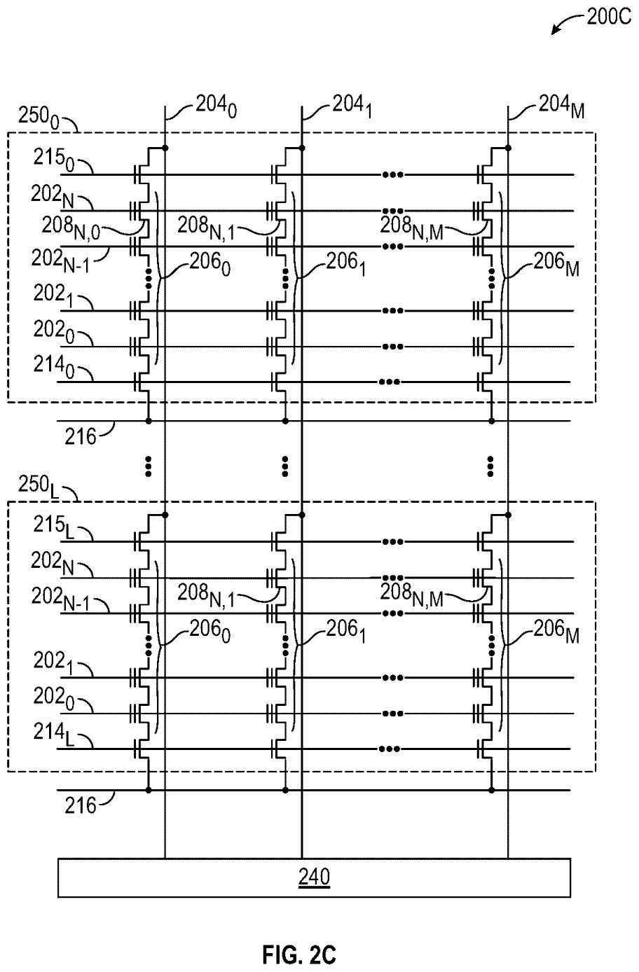

FIGS. 2A-2B are example schematics of portions of an array of memory cells 200A, such as a NAND memory array. Array of memory cells 200A may be an example of memory array 104 of a memory device 130 as described with reference to FIG. 1B according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Word lines 202 and select lines 214 and 215 of one block of memory cells 250 can have no direct connection to word lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

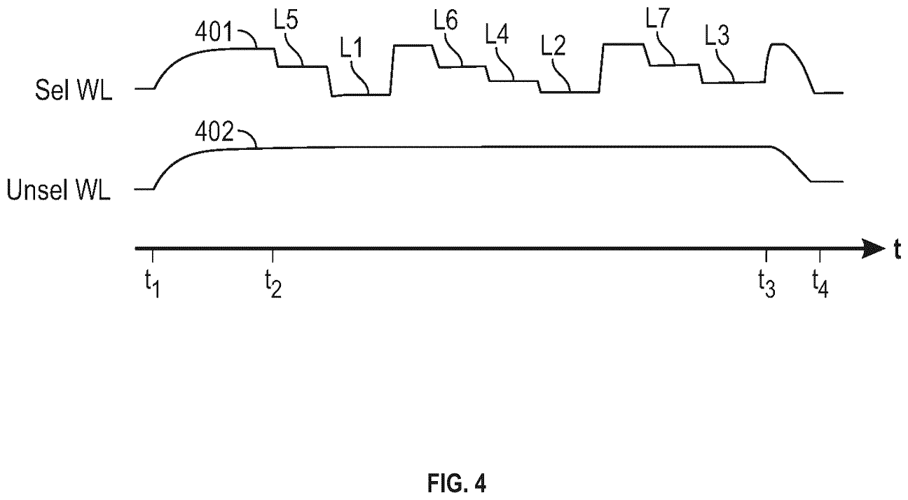

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 4-9, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1B). Apparatus 300 can be used to perform operations of a controller (e.g., to execute an operating system to perform operations corresponding to system controller 115 and/or local controller 135 of FIG. 1B).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1B). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1B). Thus, the method steps of at least some of FIGS. 4-9 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 4-9. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1B) described herein. In some examples, data storage device 320 and main memory device 330 may include one or more memory devices 130 (FIG. 1B).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

In this disclosure, the memory cell that is the target of a specific memory access operation is referred to as “selected memory cell” or “target memory cell”. The memory block where the target memory cell is located is referred to as “selected memory block”, “target memory block”, or “target block”. In the target memory block, the word line associated with the selected memory cell is referred to as the “selected word line”. The other word lines in the target memory block are referred to as the “unselected word lines”.

FIG. 4 is a timing diagram illustrating a memory access operation on a target memory block in accordance with examples as disclosed herein. The horizontal axis represents the lapse of time during a memory access operation, such as a read operation. Time intervals t₁ to t₂, t₂ to t₃, and t₃ to t₄ correspond to three phases of a read operation, namely, the prologue phase, the sensing phase (also called the reading phase), and the recovery phase, respectively. Trace 401 depicts the bias voltage waveform applied to the selected word line. Trace 402 depicts the bias voltage waveform applied to the unselected word lines. The examples discussed herein may be cross-referenced with FIG. 2C. In these examples, the target memory block is 250₀. The selected memory cell is memory cell 208_{N,0} in block 250₀. The selected world line is 202_{N} in block 250₀, and the unselected word lines are 202₀ to 202_{N-1} in block 250₀. The memory cells are of the TLC type (tri-level cells).

During the prologue phase (t₁ to t₂), a memory controller (e.g., local controller 135 as shown in FIG. 1B) controls voltage generation devices (such as word line pumps, regulators, etc.) to ramp up the bias voltage on both the selected and unselected word lines of target block 250₀. In this disclosure, the prologue phase is sometimes referred to as the “opening” phase of a read operation. Similarly, when a memory controller initiates the prologue phase for a memory block, this process is sometimes described as “opening” or “warming up” the memory block. In the opening phase, the voltage levels for both the selected and unselected word lines of the target block increase from a baseline level (e.g., 0V) to a higher voltage (e.g., Vₚₐₛₛ). Vₚₐₛₛ is a voltage level high enough to turn on all the memory cells on string 206₀. In one example, voltages of both the selected and unselected word lines reach the same level at time t₂. In other examples, voltages of the selected and unselected word lines may reach different levels at time t₂.

During the sensing phase (t₂ to t₃), the memory controller maintains the bias voltage of the unselected word lines at Vₚₐₛₛ, as indicated by the flat portion of trace 402 between times t₂ and t₃. At the same time, the memory controller performs multiple sensing operations on the selected word line 202_{N} in block 250₀ to ascertain the actual threshold level of the selected memory cell 208_{N,0} in block 250₀. As memory cell 208_{N,0} may exhibit threshold levels ranging from L0 to L7, multiple sensing operations are performed to read the lower page (at levels L5 and L1), the upper page (at levels L6, L4, and L2), and the extra page (at levels L7 and L3) of the memory cell. It should be noted that the sensing sequence illustrated in the figure is merely an example. The memory controller may employ different sensing sequences. In the example shown, a reverse read is applied where the sensing voltage is applied from high to low during the reading of each page. In other examples, a reverse read may be applied where the sensing order of each page is reversed.

During the recovery phase (t₃ to t₄), the voltage of the selected word line is equilibrated with the voltage of the unselected word line to a level in-between Vₚₐₛₛ and the last level of the sensing phase. Subsequently, all word line voltages are discharged to the baseline level (e.g., 0V) at time t₄. In this disclosure, the recovery phase is sometimes referred to as the “closing” phase of a read operation. Similarly, when a memory controller initiates the recovery phase for a memory block, this process is sometimes described as “closing” or “cooling down” the memory block.

FIG. 4 shows a complete cycle of a read operation for a single memory cell. When the memory controller performs read operations of a series of memory cells, a traditional approach is for the memory controller to repeat the entire read operation cycle when reading each memory cell. To optimize performance and reduce the overall access time, different strategies can be applied depending on whether the read sequence is sequential read or random read. Sequential read refers to accessing multiple memory cells in a predefined order within the same memory block. Random read refers to accessing memory cells randomly across the same or different memory blocks.

In a sequential read scenario, referring again to FIG. 2C, memory block 250₀ comprises M+1 strings, labeled 206₀ to 206_{M}. After completing the read operation of memory cell 208_{N,0} on string 206₀ of block 250₀, the memory controller may continue reading memory cells on the same word line across other strings of the same memory block 250₀, such as memory cells 208_{N,1} to 208_{N,M} M in block 250₀. When conducting sequential read of a series of memory cells, the overall access time for the combined read operation may be reduced by having a single prologue phase, followed by multiple sensing phases for each memory cell, and concluding with a single recovery phase. In some examples, the recovery phase is entered before the memory controller starts to read memory cells located on other word lines.

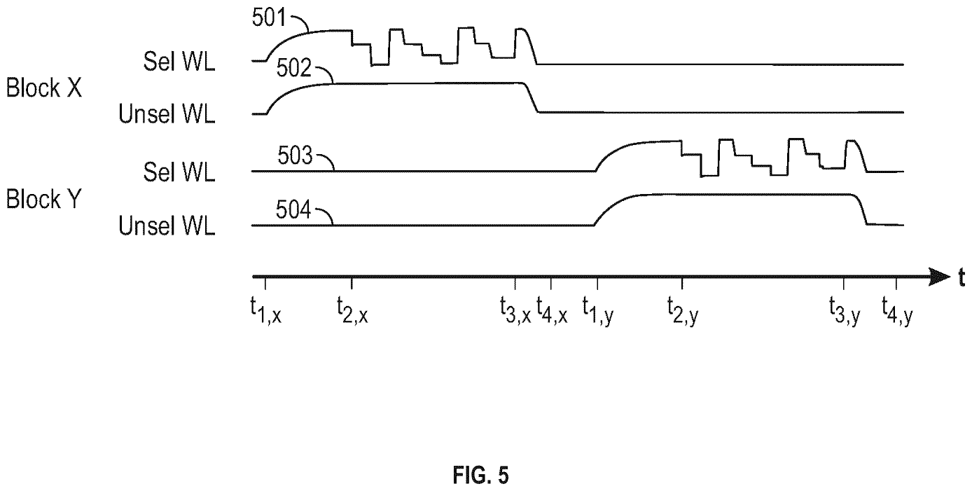

This disclosure introduces techniques to improve the overall access time in random read scenarios. FIG. 5 is a timing diagram illustrating memory read operations accessing memory cells across two memory blocks in a random read scenario, in accordance with examples as disclosed herein. The examples discussed herein may also be cross-referenced with FIG. 2C. In these examples, Block X corresponds to memory block 250₀, while Block Y corresponds to memory block 250_{L}. In some examples, the two memory blocks may be located on the same memory plane, such as in FIG. 2C. In other examples, they may be located on different memory planes.

Trace 501 depicts the bias voltage waveform applied to the selected word line (e.g., 202_{N}) in Block X. Trace 502 depicts the bias voltage waveform applied to the unselected word lines (e.g., 202₀ to 202_{N-1}) in Block X. Similarly, trace 503 depicts the bias voltage waveform applied to the selected word line (e.g., 202_{N}) in Block Y, while trace 504 depicts the bias voltage waveform applied to the unselected word lines (e.g., 202₀ to 202_{N-1}) in Block Y.

In the random read scenario illustrated in FIG. 5, the memory controller performs a first read operation on memory cell 208_{N,0} in Block X, followed by a second read operation on memory cell 208_{N,0} in Block Y. The first read operation includes the prologue phase, the sensing phase, and the recovery phase, corresponding to time periods t_{1,x} to t_{2,x}, t_{2,x} to t_{3,x}, and t_{3,x} to t_{4,x}, respectively. The second read operation includes these same three phases, represented by time periods t_{1,y} to t_{2,y}, t_{2,y} to t_{3,y}, and t_{3,y} to t_{4,y}. Under this approach, the overall access time for reading multiple memory cells is not optimized because an entire read operation cycle is repeated when accessing each memory cell. To optimize the overall access time in random read scenarios, several approaches are introduced below.

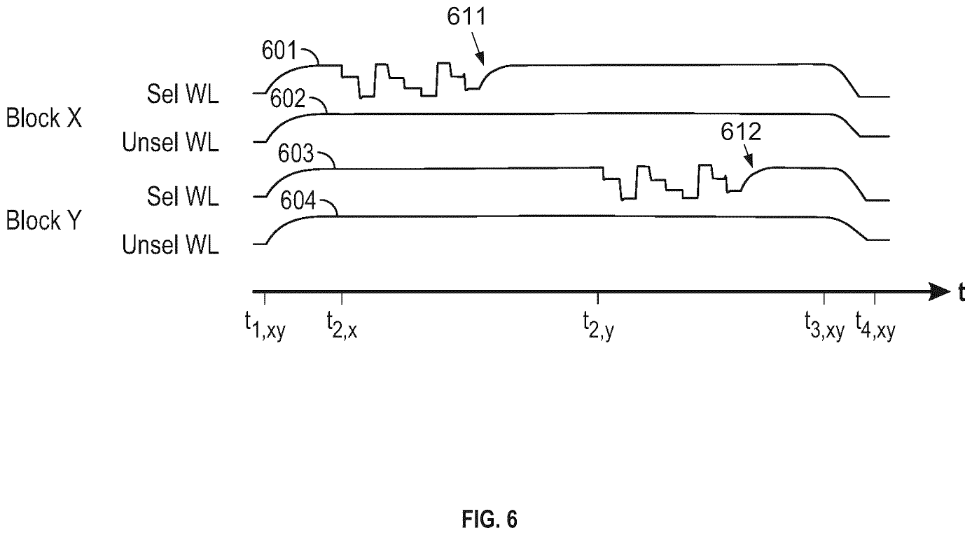

FIG. 6 is a timing diagram illustrating memory read operations accessing memory cells across two memory blocks in a random read scenario using “warm-up all-at-once” approach, in accordance with examples as disclosed herein. Referencing again with FIG. 2C, Block X corresponds to memory block 250₀, while Block Y corresponds to memory block 250_{L}. Trace 601 depicts the bias voltage waveform applied to the selected word line (e.g., 202_{N}) in Block X. Trace 602 depicts the bias voltage waveform applied to the unselected word lines (e.g., 202₀ to 202_{N-1}) in Block X. Trace 603 depicts the bias voltage waveform applied to the selected word line (e.g., 202_{N}) in Block Y, while trace 604 depicts the bias voltage waveform applied to the unselected word lines (e.g., 202₀ to 202_{N-1}) in Block Y.

At the start of the process, a system controller (e.g., system controller 115 as shown in FIG. 1A) issues commands to a memory controller (e.g., local controller 135 as shown in FIGS. 1A and 1B) to open a list of target blocks (Blocks X and Y in this example) for random read operations. The system controller can issue the commands because the system controller anticipates that the next two read operations will be targeting memory cells located in Blocks X and Y. In response to this command, the memory controller “warms up” the two blocks in parallel by causing Blocks X and Y to enter into the prologue phase, as shown during the time period t_{1,xy} to t_{2,x} in FIG. 6.

Subsequently, the memory controller performs the first read operation on Block X, as indicated by trace 601 starting at time t_{2,x}. The first read operation is performed while keeping Block Y open, with its word lines maintained at Vₚₐₛₛ, as shown by traces 603 and 604 starting at time t_{2,x.} After completing the first read operation, instead of discharging Block X as in the traditional approach, the memory controller deselects the selected word line of Block X (as indicated by arrow 611) and keeps all the word lines of Block X at a high voltage (e.g., Vₚₐₛₛ). At this point, Block X is now a “warm block”, which refers to a memory block that has been accessed at least once followed by all the word lines being kept at a high voltage. In this way, if another read operation is required for Block X, the memory controller can enter the sensing phase without warming up Block X again.

While the word lines of Block X remain at a high voltage, the memory controller performs the second read operation on Block Y, as indicated by trace 603 starting at time t_{2,y}. After the second read operation is completed, the memory controller deselects the selected word line of Block Y (as indicated by arrow 612) and keeps all the word lines of Block Y at a high voltage (e.g., Vₚₐₛₛ). Similarly, Block Y is now a “warm block” and if another read operation is required for Block Y, the memory controller can enter the sensing phase without warming up Block Y again.

Finally, at time t_{3,xy}, when it is determined that no further read operations are required for Blocks X and Y, or when a series of read operations are completed, the memory controller closes both blocks at the same time by discharging their word lines.

Compared to the approach shown in FIG. 5, where Blocks X and Y are warmed up and cooled down at separate times, here the two blocks are warmed up and cooled down at the same time. As a result, the overall access time for reading two memory cells across separate memory blocks can be reduced. In addition, when multiple read operations are required for one memory block, the memory block will be kept warm after the first read operation. As a result, the overall access time for reading multiple memory cells in a memory block can also be reduced.

FIG. 6 shows the “warm-up all-at-once” approach applied to two read operations accessing two memory blocks. However, this is intended for illustrative purpose only. The approach can be extended to more than two read operations accessing multiple memory blocks. For example, if a third read operation targets memory cells in Block Z (not shown in the figure), the system controller may issue commands to open Blocks X, Y, and Z. The memory controller can then warm up the three blocks in parallel by ramping up the bias voltage on the word lines of Blocks X, Y, and Z. After the three read operations are completed, the memory controller can close all the blocks in parallel by discharging the word lines of Blocks X, Y, and Z.

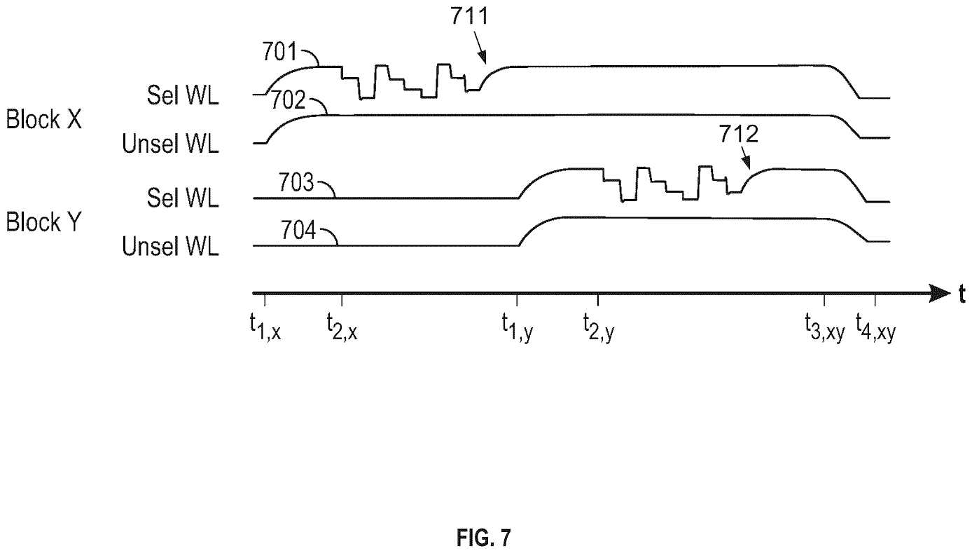

FIG. 7 is a timing diagram illustrating memory read operations accessing memory cells across two memory blocks in a random read scenario using “warm-up on-need” approach, in accordance with examples as disclosed herein. Similar to FIG. 6, and referencing again with FIG. 2C, Block X corresponds to memory block 250₀, while Block Y corresponds to memory block 250_{L}. Trace 701 depicts the bias voltage waveform applied to the selected word line (e.g., 202_{N}) in Block X. Trace 702 depicts the bias voltage waveform applied to the unselected word lines (e.g., 202₀ to 202_{N-1}) in Block X. Trace 703 depicts the bias voltage waveform applied to the selected word line (e.g., 202_{N}) in Block Y, while trace 704 depicts the bias voltage waveform applied to the unselected word lines (e.g., 202₀ to 202_{N-1}) in Block Y.

At the start of the process, a system controller (e.g., host system controller 106 or memory system controller 115 as shown in FIG. 1A) issues a first memory read request to a memory controller (e.g., local controller 135 as shown in FIG. 1B) to read memory cell 208_{N,0} in Block X. In response to this request, the memory controller warms up Block X to enter into the prologue phase, as shown during the time period t_{1,x} to t_{2,x} in FIG. 7. The memory controller then performs the first read operation on Block X, as indicated by trace 701 starting at time t_{2,x}. After completing the first read operation, instead of discharging Block X, the memory controller deselects the selected word line of Block X (as indicated by arrow 711) and keeps all the word lines of Block X at a high voltage (e.g., Vₚₐₛₛ) to make it a “warm block”.

Traces 703 and 704 remain at a baseline level (e.g., 0V) before time t_{1,y}. At this point, Block Y is a “cold block”, which refers to a memory block that has not been accessed. At time t_{1,y}, the system controller issues a second memory read request to the memory controller to read memory cell 208_{N,0} in Block Y. Since Block Y is a cold block, the memory controller needs to first warm up Block Y to enter into the prologue phase, as shown during the time period t_{1,y} to t_{2,y} in FIG. 7. The memory controller then performs the second read operation on Block Y, as indicated by trace 703 starting at time t_{2,y}. After the second read operation is completed, the memory controller deselects the selected word line of Block Y (indicated by arrow 712) and keeps all the word lines of Block Y at a high voltage (e.g., Vₚₐₛₛ). Block Y now becomes a “warm block”. If another read operation is required for Block Y, the memory controller can enter the sensing phase without warming up Block Y again.

Finally, at time t_{3,xy}, when it is determined that no further read operations are required for Blocks X and Y, or when a series of read operations are completed, the memory controller closes both blocks in parallel by discharging their word lines.

Compared to the approach shown in FIG. 5, where Blocks X and Y are cooled down at separate times, here the two blocks are cooled down at the same time. As a result, the overall access time for reading two memory cells across separate memory blocks can also be reduced. In addition, when multiple read operations are required for one memory block, the memory block will be kept warm after the first read operation. As a result, the overall access time for reading multiple memory cells in a memory block can also be reduced.

Compared to the warm-up all-at-once approach shown in FIG. 6, where Blocks X and Y are warmed up in parallel at the beginning, the warm-up on-need approach warms up a memory block when needed. In this example, before the process starts, both Blocks X and Y are cold blocks. Block X was warmed up because a first memory read request to access Block X was received. Block Y remains a cold block because no memory read request was received to access Block Y. Block Y was warmed up later when it needs to be warmed up when the second memory read request was received.

The warm-up on-need approach also entails that when the memory controller receives a command from the system controller to warm up a memory block, the memory controller may independently determine whether the block is a warm or cold block, and only warms up the block if it is a cold block. For example, referring still to FIG. 7, if at time t_{3,xy} the memory controller receives a command to warm up Block X (not shown in the figure), the memory controller first determines if Block X is a warm block. In this case, since Block X is already a warm block at t_{3,xy}, there is no need to warm up Block X again at this time.

Memory block cool-down also have two approaches, namely, “cool-down all-at-once” and “cool-down on-need”. The cool-down all-at-once approach, as shown in FIGS. 6 and 7, discharges the word lines of Blocks X and Y in parallel during the time period t_{3,xy} to t_{4,xy} in both figures. In contrast, the cool-down on-need approach discharges memory blocks independently based on specific criteria. For example, warm-up timers may be used to track the duration of memory blocks that remain open (or kept warm). If a warm-up timer exceeds a timeout threshold, the corresponding memory block may be closed and its word lines discharged. This may mitigate the effect of read disturb on memory cells when word lines in the memory block are biased at a high voltage for a prolonged period of time. In some examples, the timeout threshold may be adjusted at runtime based on temperature coefficients of the NAND device.

As previously discussed, decisions regarding when to open or close a memory block may be made by the system controller (e.g., host system controller 106 or memory system controller 115), or by the memory controller (e.g., local controller 135). This distinction gives rises to two approaches when warming up and cooling down memory blocks, namely, the “totally-owned-by-system” approach and the “mixed ownership” approach, depending on where the decision is made.

In the totally-owned-by-system approach, the system controller directly issues commands to open or close a target block. These commands may include open-only, open-and-read, read-only, and close-only, etc., corresponding to different phases of a read operation. For example, an open-and-read command instructs the memory controller to open the target block and then perform a read, while a read-only command simply reads the target block that is already open. The system controller may keep track of the status of opened blocks to ensure that a limited number of blocks are opened at any given time, or to prevent issuing an open command on a target block that is already open. Upon receiving the commands, the memory controller follows the commands without making its own decisions about when to open or close a target block. For example, in FIG. 6, when opening a memory block, the system controller decides at time t_{1,xy} that Blocks X and Y are the next target blocks, and therefore issues commands to the memory controller to open the two blocks. Upon receiving the commands, the memory controller executes them to open the two blocks without making its own independent decision about whether the blocks should be opened.

When closing a memory block in the totally-owned-by-system approach, the system controller in FIG. 6 decides at time t_{3,xy} that no further read operations are required for Blocks X and Y, and therefore issues commands to the memory controller to close the two blocks. Upon receiving the commands, the memory controller executes them to close the two blocks without making its own independent decision about whether the blocks should be closed. For another example, the warm-up timers can be maintained by a system controller in this approach. The system controller may track the duration of the memory blocks that are opened, and issue commands to the memory controller to close the block if the warm-up timer exceeds a threshold. The memory controller then executes the commands to close the two blocks without making its own independent decision.

In the mixed ownership approach, the system controller issues requests to access a target block. The memory controller keeps track of opened blocks and determines whether the requested target block should be opened. In response to a request to access a target block, if the target block is currently closed, the memory controller may open the block. Otherwise, if the target block is already opened, the memory controller will not open the block again. In this case, the memory controller may inform the system controller that the request has been denied, along with the reasons of the denial. If the number of opened blocks reaches a limit, the memory controller may also deny the system controller's request to open the block, and provide the reason that a maximum number of opened blocks has been reached. In some embodiments, the memory controller may simply ignore the system controller's request.

In the mixed ownership approach, after certain blocks are opened, the memory controller may also make its own independent decisions on when to close an opened block. For example, the warm-up timers can be maintained by the memory controller to track the duration of the memory blocks that are open. The memory controller can make its own independent decisions to close an opened memory block if the warm-up timer exceeds a threshold. In one example, the system controller may issue commands to the memory controller to enable or disable the warm-up timer.

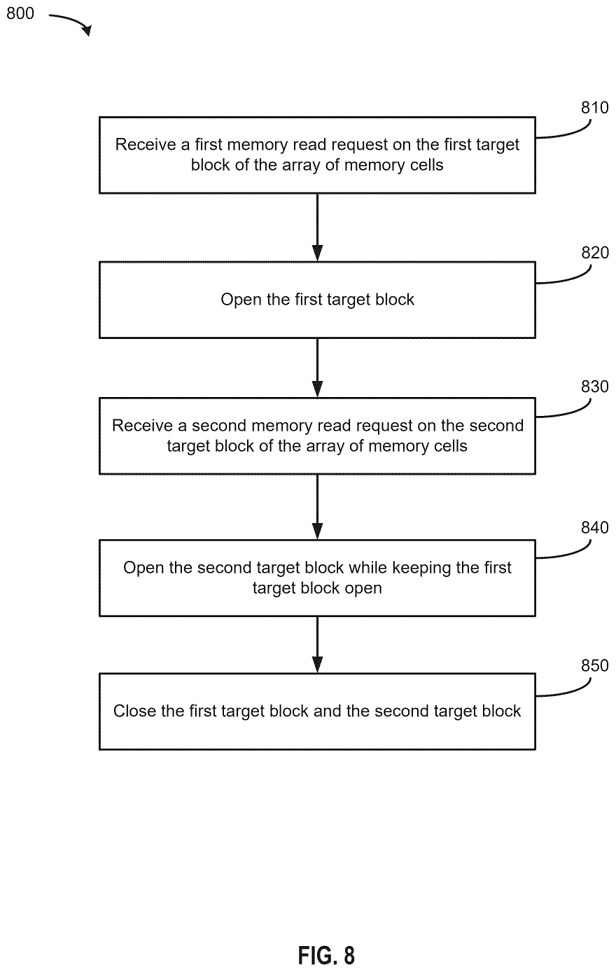

FIG. 8 is a flowchart illustrating method 800 for performing random read operations on two target blocks using the warm-up on-need approach, in accordance with examples as disclosed herein. Method 800 may be performed by a memory device, or memory controllers in a memory device, such as a local controller 135. In some embodiments, method 800 can be implemented in the form of firmware that is stored in computer readable medium and executed by local controller 135 to cause the memory device 130 to perform the operations described herein.

At block 810, the memory controller receives a first memory read request on the first target block of the array of memory cells. In one example, referring back to FIG. 7, the memory controller receives the first memory read request from a system controller (e.g., host system controller 106 or memory system controller 115) to read a target memory cell in the first target block (Block X).

At block 820, the memory controller opens the first target block. Referring to FIG. 7, in response to the first memory read request, the memory controller warms up Block X to enter into the prologue phase, as shown during the time period t_{1,x} to t_{2,x}. In one example, the memory controller then performs a read operation on Block X.

At block 830, the memory controller receives a second memory read request on the second target block of the array of memory cells. Referring to FIG. 7, the memory controller receives the second memory read request from the system controller to read a target memory cell in the second target block (Block Y) at time t_{1,y}.

At block 840, the memory controller opens the second target block while keeping the first target block open. Referring to FIG. 7, since Block Y is a cold block, the memory controller warms up Block Y to enter into the prologue phase, as shown during the time period t_{1,y} to t_{2,y}. In one example, the memory controller then performs a read operation on Block Y.

At block 850, the memory controller closes the first target block and the second target block. Referring to FIG. 7, at time t_{3,xy}, when it is determined that no further read operations are required for Blocks X and Y, or when a series of read operations are completed, the memory controller closes both blocks in parallel by discharging their word lines.

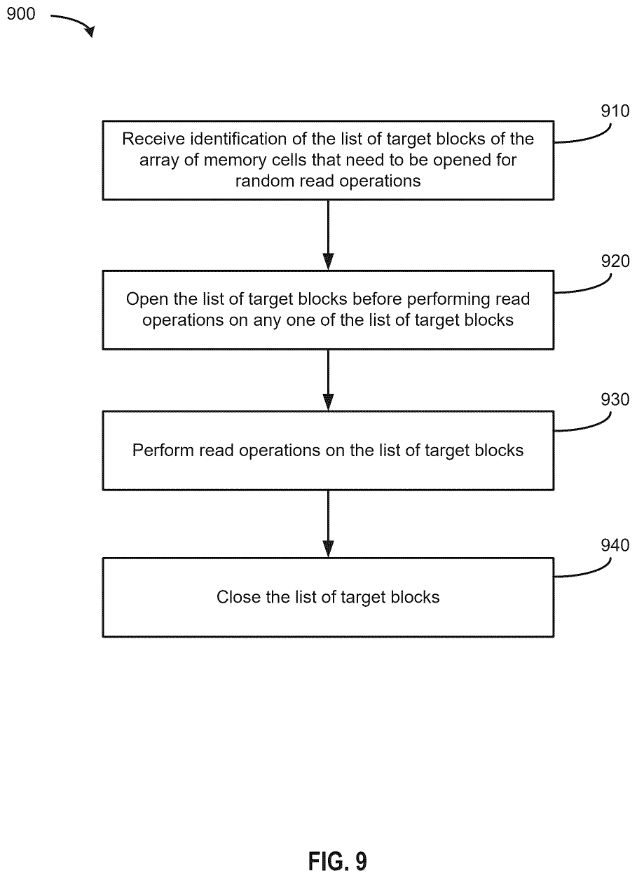

FIG. 9 is a flowchart illustrating method 900 for performing random read operations on a list of target blocks using the warm-up all-at-once approach, in accordance with examples as disclosed herein. Method 900 may be performed by a memory device, or memory controllers in a memory device, such as a local controller 135. In some embodiments, method 900 can be implemented in the form of firmware that is stored in computer readable medium and executed by local controller 135 to cause the memory device 130 to perform the operations described herein.

At block 910, the memory controller receives identification of the list of target blocks of the array of memory cells that need to be opened for random read operations. In one example, referring back to FIG. 6, the memory controller receives a command from a system controller (e.g., host system controller 106 or memory system controller 115) to open a list of target blocks (Blocks X and Y).

At block 920, the memory controller opens the list of target blocks before performing read operations on any one of the list of target blocks. Referring to FIG. 6, in response to the command, the memory controller warms up the two blocks in parallel by causing Blocks X and Y to enter into the prologue phase, as shown during the time period t_{1,xy} to t_{2,x}.

At block 930, the memory controller performs read operations on the list of target blocks. Referring to FIG. 6, the memory controller performs the first read operation on Block X, as indicated by trace 601 starting at time t_{2,x}. In one example, after completing the first read operation, the memory controller deselects the selected word line of Block X and keeps all the word lines of Block X at a high voltage (e.g., Vₚₐₛₛ). The memory controller then performs the second read operation on Block Y starting at time t_{2,y}.

At block 940, the memory controller closes the list of target blocks. Referring to FIG. 6, at time t_{3,xy}, when it is determined that no further read operations are required for Blocks X and Y, or when a series of read operations are completed, the memory controller closes both blocks in parallel by discharging their word lines.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells;
a plurality of word lines coupled to the array of memory cells, and
a memory controller configured to perform random read operations on at least two target blocks including a first target block and a second target block, the memory controller being configured to:
receive a first memory read request on the first target block of the array of memory cells;
open the first target block;
receive a second memory read request on the second target block of the array of memory cells;
open the second target block while keeping the first target block open; and
close the first target block and the second target block.

2. The memory device of claim 1, wherein the first memory read request is a request for random read.

3. The memory device of claim 1, wherein the second memory read request is of a same type as the first memory read request.

4. The memory device of claim 1, wherein the memory controller is further configured to:
subsequent to opening the first target block, perform read operations on the first target block.

5. The memory device of claim 1, wherein the memory controller is further configured to:
subsequent to opening the second target block while keeping the first target block open, perform read operations on the second target block.

6. The memory device of claim 1, wherein opening the first target block comprises:
increasing bias voltages applied to the word lines coupled to the first target block if the first target block is not already opened.

7. The memory device of claim 1, wherein opening the second target block comprises:
increasing bias voltages applied to the word lines coupled to the second target block if the second target block is not already opened.

8. The memory device of claim 1, wherein closing the first target block and the second target block comprises:
discharging the word lines coupled to the first target block and the second target block.

9. The memory device of claim 1, wherein closing the first target block and the second target block comprises:
closing one of the first target block or the second target block when an open timer of the one of the first target block or the second target block exceeds a predetermined threshold.

10. A system comprising:
a processor;
an array of memory cells;
a plurality of word lines coupled to the array of memory cells,
a first memory controller configured to provide a list of target blocks in the array of memory cells for performing random read operations; and
a second memory controller configured to:
receive a first memory read request on the first target block of the array of memory cells;
open the first target block;
receive a second memory read request on the second target block of the array of memory cells;
open the second target block while keeping the first target block open; and
close the first target block and the second target block.

11. A memory device comprising:
an array of memory cells;
a plurality of word lines coupled to the array of memory cells, and
a memory controller configured to perform random read operations on a list of target blocks, the memory controller being configured to:
receive identification of the list of target blocks of the array of memory cells that need to be opened for random read operations;
open the list of target blocks before performing read operations on any one of the list of target blocks;
perform read operations on the list of target blocks; and
close the list of target blocks.

12. The memory device of claim 11, wherein opening the list of target blocks comprises:
increasing bias voltages applied to the word lines coupled to target blocks in the list of target blocks that are not already opened.

13. The memory device of claim 11, wherein closing the list of target blocks comprises:
discharging the word lines coupled to the list of target blocks.

14. The memory device of claim 11, wherein closing the list of target blocks comprises:
receiving identification of an opened block in the list of target block that needs to be closed for random read operations;
closing the opened block.

15. The memory device of claim 11, wherein closing the list of target blocks comprises:
closing a block in the list of target blocks when an open timer of the block exceeds a predetermined threshold.

16. A system comprising:
a processor;
an array of memory cells;
a plurality of word lines coupled to the array of memory cells,
a first memory controller configured to provide commands for performing random read operations on a list of target blocks of the array of memory cells, and
a second memory controller configured to,
receive, from the first memory controller, a command comprising a list of target blocks of the array of memory cells that need to be opened for random read operations;
open the list of target blocks before performing read operations on any one of the list of target blocks;
perform read operations on the list of target blocks; and
close the list of target blocks.

17. The system of claim 16, wherein the commands provided by the first memory controller includes at least one of:
a command to open the list of target blocks;
a command to perform read operation on one or more blocks in the list of target blocks; or
a command to close the one or more blocks.

18. The system of claim 16, wherein opening the list of target blocks comprises:
increasing bias voltages applied to the word lines coupled to target blocks in the list of target blocks that are not already opened.

19. The system of claim 16, wherein closing the list of target blocks comprises:
discharging the word lines coupled to the list of target blocks.
